(19) United States
(12) Patent Application Publication
(10) Pub. No.: US 2023/0022071 A1
(43) Pub. Date: Jan. 26, 2023

(54) APPARATUS COMPRISING SILICON CARBIDE MATERIALS AND RELATED ELECTRONIC SYSTEMS AND METHODS

(71) Applicant: Micron Technology, Inc., Boise, ID (US)

(72) Inventors: Chunhua Yao, Boise, ID (US); Song Guo, Boise, ID (US); Vivek Yadav, Boise, ID (US)

(21) Appl. No.: 17/813,080

(22) Filed: Jul. 18, 2022

Related U.S. Application Data
(60) Provisional application No. 63/225,198, filed on Jul. 23, 2021.

(51) Int. Cl. H01L 27/108

(52) U.S. Cl. CPC H01L 27/10888; H01L 27/10814

(57) ABSTRACT

An apparatus comprising active areas and shallow trench isolation structures on a base material. A first conductive material is vertically adjacent to an active area of the active areas and between laterally adjacent shallow trench isolation structures. A second conductive material is vertically adjacent to the first conductive material and between the laterally adjacent shallow trench isolation structures. A silicon carbide material is on sidewalls of the shallow trench isolation structures and exhibits substantially vertical sidewalls. An oxide material is adjacent to the active areas and shallow trench isolation structures, a nitride material is adjacent to the oxide material, and a digit line is adjacent to the second conductive material. An electronic system and methods of forming an apparatus are also disclosed.

### CROSS-REFERENCE TO RELATED APPLICATION

This application claims the benefit under 35 U.S.C. § 119(e) of U.S. Provisional Patent Application Ser. No. 63/225,198, filed Jul. 23, 2021, the disclosure of which is hereby incorporated herein in its entirety by this reference.

### TECHNICAL FIELD

Embodiments disclosed herein relate to an apparatus and methods of forming an apparatus. More particularly, embodiments of the disclosure relate to methods of using a silicon carbide material as a liner to form smaller openings, and to related apparatus containing the silicon carbide material.

### BACKGROUND

Electronic device designers desire to increase the level of integration or density of features within an electronic device by reducing the dimensions of individual features and by reducing the separation distance between neighboring features. In addition, electronic device designers often desire to design architectures that are not only compact, but offer performance advantages, as well as simplified designs. A relatively common electronic device is a memory device. A memory device may include a memory array having a number of memory cells arranged in a grid pattern. One type of memory cell is a dynamic random access memory (DRAM) device, which is a volatile memory device that may lose a stored state over time unless the DRAM device is periodically refreshed by an external power supply. In the simplest design configuration, a DRAM cell includes one access device (e.g., a transistor) and one storage device (e.g., a capacitor). Modern applications for memory devices may utilize vast numbers of DRAM unit cells, arranged in an array of rows and columns. The DRAM cells are electrically accessible through digit lines and word lines arranged along the rows and columns of the array.

Dry etch processes are used in many memory device fabrication processes due to directionality of the plasma that is achieved during the dry etch process. The plasma directionality of the dry etch process enables materials to be etched to exhibit vertical sidewalls. The dry etch processes are used, for example, in processes where small features are desired. Openings are formed by photolithography processes in a material to a desired critical dimension (CD) and a liner is conformally formed on sidewalls of the material defining the openings. Portions of the liner within the openings are removed by the dry etch processes, while remaining portions of the liner narrow (e.g., reduce, shrink) the size of the openings, enabling the small features to be formed in the reduced-sized openings. Materials of the features are subsequently formed in the openings and the resulting features are smaller in size than the CD of the openings. As sizes of the features of memory devices continue to decrease, the ability to form the openings at the desired CD and remove the desired portions of the liner becomes harder. The dry etch processes used to remove portions of the liner have drawbacks including causing surface damage to underlying materials or producing undesirable profiles in the underlying materials. Surface damage to the underlying materials may result in reduced electrical performance. If portions of the underlying material are removed by the dry etch process, the liner may exhibit shoulders rather than the desired substantially horizontal and substantially vertical surfaces. The shoulders may cause shorting between adjacent features.

### BRIEF DESCRIPTION OF THE DRAWINGS

FIGS. 1A through 1F are simplified partial cross-sectional views showing a method of forming an apparatus in accordance with embodiments of the disclosure;

FIG. 2 is a simplified block diagram of a microelectronic device (e.g., a DRAM device, a memory device) including an apparatus in accordance with embodiments of the disclosure;

FIGS. 3A and 3B are cross-sectional views of a portion of a microelectronic device (e.g., a DRAM device, a memory device) including an apparatus in accordance with embodiments of the disclosure; and

FIG. 4 is a simplified block diagram of a system implemented in accordance with some embodiments of the disclosure.

### DETAILED DESCRIPTION

An apparatus (e.g., a microelectronic device, a semiconductor device, a memory device) that includes a liner adjacent to (e.g., over) one or more materials is disclosed. The liner includes a silicon carbide material, such as a doped silicon-containing material that also contains carbon atoms (e.g., a doped silicon carbide material). The liner is formed in small openings, such as those having a width of less than or equal to about 35 nm. The silicon carbide material of the liner is conformally formed in the openings. After formation, portions of the silicon carbide material are exposed to a plasma treatment act, which changes a chemical composition of the exposed portions of the liner. After the plasma treatment, the exposed portions of the liner are selectively removed (e.g., selectively etched) from the openings by a wet etch act, while unexposed portions of the liner remain in the openings, reducing the width within the openings. By conducting the plasma treatment act on the silicon carbide material as initially formed, the exposed portions and unexposed portions of the liner may exhibit different chemical compositions, enabling the exposed portions of the liner to be selectively removed by the wet etch act while the unexposed portions of the liner remain in the openings. The reduced width openings enable smaller features (e.g., smaller than a critical dimension (CD) of the openings) to be formed in the openings. The exposed portions of the liner are also selectively removed compared to other exposed materials of the apparatus. The remaining portions of the liner in the openings may exhibit substantially square corners.

The following description provides specific details, such as material types, material thicknesses, and process conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete description of an electronic device or a complete process flow for manufacturing the electronic device and the structures described below do not form a complete electronic device. Only those process acts and structures necessary to understand the embodiments described herein are described in detail below. Additional acts to form a complete electronic device may be performed by conventional techniques.

Drawings presented herein are for illustrative purposes only, and are not meant to be actual views of any particular material, component, structure, electronic device, or electronic system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, the singular forms “a,” “an” and “the” are intended to include the plural forms as well, unless the context clearly indicates otherwise.

As used herein, “and/or” includes any and all combinations of one or more of the associated listed items.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the term “conductive material” means and includes an electrically conductive material. The conductive material may include, but is not limited to, one or more of a doped polysilicon, undoped polysilicon, a metal, an alloy, a conductive metal oxide, a conductive metal nitride, a conductive metal silicide, and a conductively doped semiconductor material. By way of example only, the conductive material may be one or more of tungsten (W), tungsten nitride (WN_{y}), nickel (Ni), tantalum (Ta), tantalum nitride (TaN_{y}), tantalum silicide (TaSiₓ), platinum (Pt), copper (Cu), silver (Ag), gold (Au), aluminum (Al), molybdenum (Mo), titanium (Ti), titanium nitride (TiN_{y}), titanium silicide (TiSiₓ), titanium silicon nitride (TiSiₓN_{y}), titanium aluminum nitride (TiAlₓN_{y}), molybdenum nitride (MoNₓ), iridium (Ir), iridium oxide (IrO_{z}), ruthenium (Ru), ruthenium oxide (RuO_{z}), n-doped polysilicon, p-doped polysilicon, undoped polysilicon, and conductively doped silicon.

As used herein, the term “configured” refers to a size, shape, material composition, and arrangement of one or more of at least one structure and at least one apparatus facilitating operation of one or more of the structure and the apparatus in a pre-determined way.

As used herein, the term “dielectric material” means and includes an electrically insulative material. The dielectric material may include, but is not limited to, one or more of an insulative oxide material or an insulative nitride material. A dielectric oxide may be an oxide material, a metal oxide material, or a combination thereof. The dielectric oxide may include, but is not limited to, a silicon oxide (SiOₓ, silicon dioxide (SiO₂)), doped SiOₓ, phosphosilicate glass, borosilicate glass, borophosphosilicate glass, fluorosilicate glass, tetraethylorthosilicate (TEOS), aluminum oxide (AlOₓ), gadolinium oxide (GdOₓ), hafnium oxide (HfOₓ), magnesium oxide (MgOₓ), niobium oxide (NbOₓ), tantalum oxide (TaOₓ), titanium oxide (TiOₓ), zirconium oxide (ZrOₓ), hafnium silicate, a dielectric oxynitride material (e.g., SiOₓN_{y}), a dielectric carboxynitride material (e.g., SiOₓC_{z}N_{y}), a combination thereof, or a combination of one or more of the listed materials with silicon oxide. A dielectric nitride material may include, but is not limited to, silicon nitride.

As used herein, the terms “different chemical compositions” or “different material compositions” mean and include a chemical composition of a portion of a liner material differing in the relative ratio of one or more chemical elements from a chemical composition of another portion of the liner material. For example, if the liner material is a doped silicon-containing material, the chemical composition, one portion of the liner material may include a higher carbon content than another portion of the liner material.

As used herein, the term “digit line” may be otherwise known and referred to in the art as a “bit line” or as a “sense line.”

As used herein, the term “electronic device” includes, without limitation, a memory device, as well as semiconductor devices which may or may not incorporate memory, such as a logic device, a processor device, or a radiofrequency (RF) device. Further, an electronic device may incorporate memory in addition to other functions such as, for example, a so-called “system on a chip” (SoC) including a processor and memory, or an electronic device including logic and memory. The electronic device may be a 3D electronic device, such as a 3D DRAM device.

As used herein, the term “liner material” or “liner” means and includes a silicon carbide material or a doped silicon-containing material, such as a doped silicon carbide material, formulated to exhibit etch selectivity relative to other exposed materials when subjected to the same etch conditions. The liner may include one or more materials, such as a silicon carbide material, a silicon carbon oxide material, a silicon carbon nitride material, a silicon carbon boride material and one or more other materials, positioned adjacent to one another and that are formulated to exhibit the desired etch selectivity properties.

As used herein, reference to an element as being “on” or “over” another element means and includes the element being directly on top of, adjacent to (e.g., laterally adjacent to, vertically adjacent to), underneath, or in direct contact with the other element. It also includes the element being indirectly on top of, adjacent to (e.g., laterally adjacent to, vertically adjacent to), underneath, or near the other element, with other elements present therebetween. In contrast, when an element is referred to as being “directly on” or “directly adjacent to” another element, no intervening elements are present.

As used herein, the term “silicon carbide material” means and includes a material including silicon atoms and carbon atoms, and, optionally one or more of oxygen atoms, nitrogen atoms, or boron atoms. Therefore, the term includes silicon carbide, silicon carbon oxide, silicon carbon nitride, silicon carbon oxynitride, or silicon carbon boride. The term “silicon carbide material” may also be used to collectively refer to silicon carbide (SiC) or the doped silicon carbide material.

As used herein, the term “doped silicon carbide material” means and includes a material including silicon atoms, carbon atoms, and one or more of oxygen atoms, nitrogen atoms, or boron atoms. The doped silicon carbide material may include, but is not limited to, a silicon carbon oxide material, a silicon carbon nitride material, or a silicon carbon oxynitride material. The doped silicon carbide material may also include a silicon carbon boride material or a silicon carbon oxyboride carbide material. The term “silicon carbon oxide” is used to refer to the doped silicon carbide material having a general chemical formula of SiC_{y}Oₓ, wherein one or more of the carbon atoms are bonded to the silicon atoms. The term “silicon carbon nitride” is used to refer to the doped silicon carbide material having a general chemical formula of SiCN_{y}, and the term “silicon carbon oxynitride” is used to refer to the doped silicon carbide material having a general chemical formula of SiCOₓN_{y}. The doped silicon carbide materials listed above may be a stoichiometric compound or a non-stoichiometric compound, and values of “x” and “y” may be integers or may be non-integers. The term “doped silicon carbide material” is used to collectively refer to the silicon carbon oxide material, the silicon carbon nitride material, and/or the silicon carbon oxynitride material. Silicon oxide (SiOₓ) including only silicon atoms and oxygen atoms is excluded from the definition of a doped silicon carbide material.

As used herein, the terms “selectively removable” or “selectively etchable” mean and include a material that exhibits a greater removal (e.g., etch) rate responsive to exposure to a given etch chemistry and/or process conditions relative to another material exposed to the same etch chemistry and/or process conditions. For example, the material may exhibit an etch rate that is at least about five times greater than the etch rate of another material, such as an etch rate of about ten times greater, about twenty times greater, or about forty times greater than the etch rate of the another material. Etch chemistries and etch conditions for selectively etching a desired material may be selected by a person of ordinary skill in the art.

As used herein, the term “substantially” in reference to a given parameter, property, or condition means and includes to a degree that one of ordinary skill in the art would understand that the given parameter, property, or condition is met with a degree of variance, such as within acceptable manufacturing tolerances. By way of example, depending on the particular parameter, property, or condition that is substantially met, the parameter, property, or condition may be at least 90.0% met, at least 95.0% met, at least 99.0% met, or even at least 99.9% met.

As used herein, the term “substrate” means and includes a material (e.g., a base material) or construction upon which additional materials are formed. The substrate may be a an electronic substrate, a semiconductor substrate, a base semiconductor layer on a supporting structure, an electrode, an electronic substrate having one or more materials, layers, structures, or regions formed thereon, or a semiconductor substrate having one or more materials, layers, structures, or regions formed thereon. The materials on the electronic substrate or semiconductor substrate may include, but are not limited to, semiconductive materials, insulating materials, conductive materials, etc. The substrate may be a conventional silicon substrate or other bulk substrate comprising a layer of semiconductive material. As used herein, the term “bulk substrate” means and includes not only silicon wafers, but also silicon-on-insulator (“SOT”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

As used herein, the terms “vertical,” “longitudinal,” “horizontal,” and “lateral” are in reference to a major plane of a structure and are not necessarily defined by Earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure.

Unless otherwise indicated, the materials described herein may be formed by conventional techniques including, but not limited to, spin coating, blanket coating, chemical vapor deposition (CVD), atomic layer deposition (ALD), plasma enhanced ALD, physical vapor deposition (PVD) (including sputtering, evaporation, ionized PVD, and/or plasma-enhanced CVD), or epitaxial growth. Alternatively, the materials may be grown in situ. Depending on the specific material to be formed, the technique for depositing or growing the material may be selected by a person of ordinary skill in the art.

Unless the context indicates otherwise, the removal of materials described herein may be accomplished by any suitable technique including, but not limited to, etching (e.g., dry etching, wet etching, vapor etching), ion milling, abrasive planarization, or other known methods.

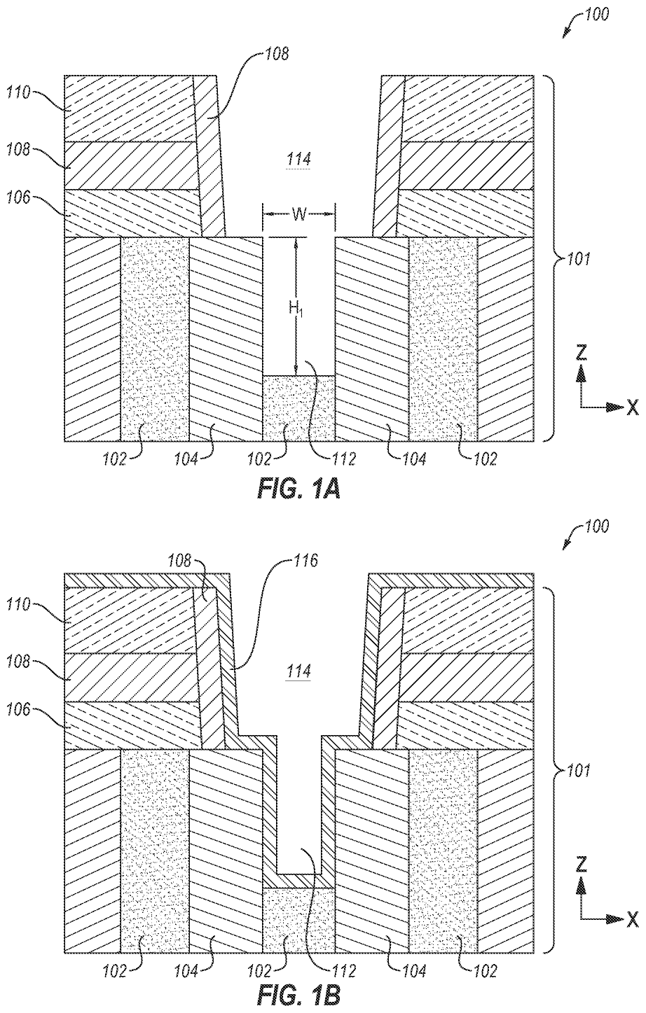

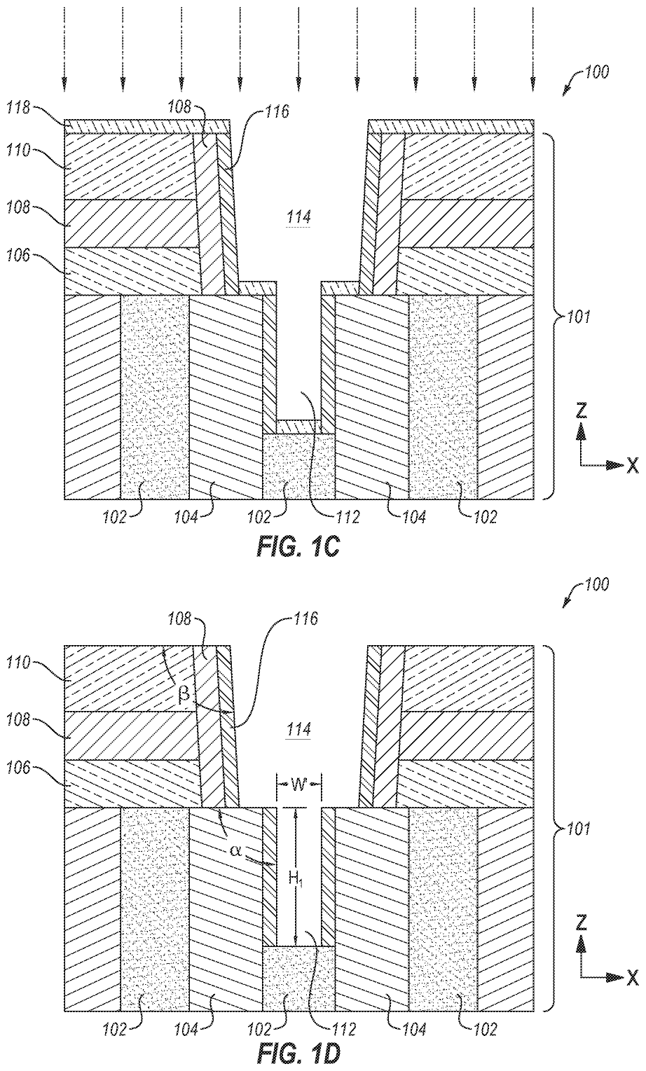

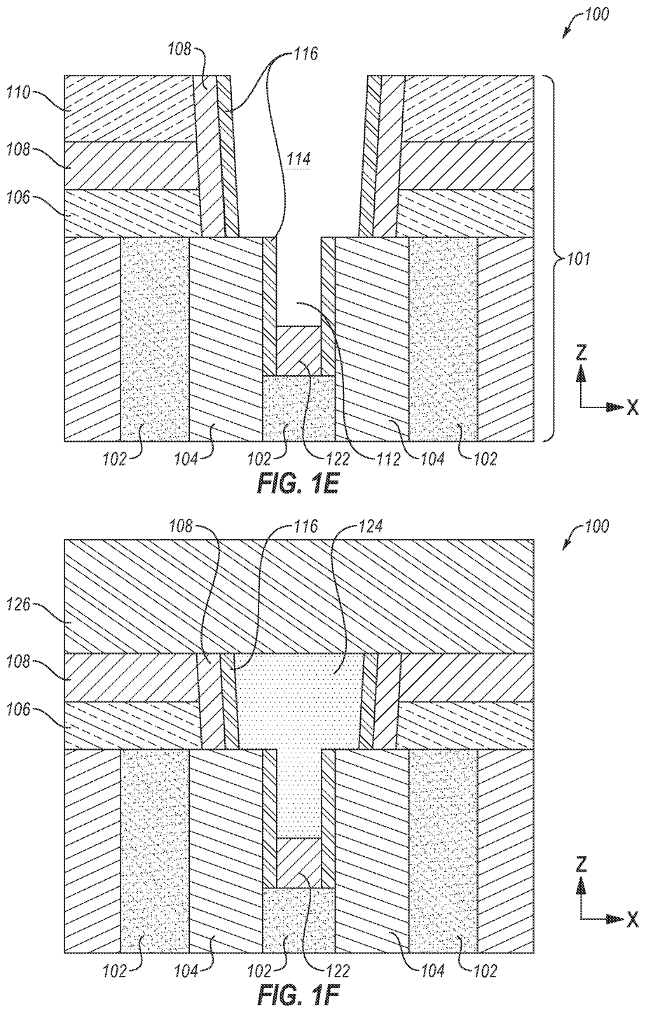

FIGS. 1A through 1F are simplified partial cross-sectional views showing embodiments of a method of forming an apparatus 100 (e.g., a microelectronic device; a semiconductor device; a memory device, such as a DRAM device). With the description provided below, it will be readily apparent to one of ordinary skill in the art that the methods described herein may be used to form various microelectronic devices and not only DRAM devices. In other words, the methods of the disclosure may be used whenever it is desired to form small features in an apparatus without conducting a dry etch process. By way of example only, the methods according to embodiments of the disclosure enable the small features, such as contacts, to be formed when the CD of other features of the apparatus is greater. The width of the features is smaller than the CD of the initially-formed openings in which the features are formed.

Referring to FIG. 1A, an apparatus 100 includes active areas 102, shallow trench isolation (STI) structures 104, a first oxide material 106, a nitride material 108, and a second oxide material 110. The apparatus 100 has been subjected to previous fabrication acts to form these components of a semiconductor structure 101 on a base material (not shown). The active areas 102 and STI structures 104 are formed by conventional techniques. The first oxide material 106 is adjacent to (e.g., on, directly on, directly contacting) the active areas 102 and the STI structures 104, and is adjacent to the nitride material 108. The nitride material 108 includes a horizontal portion and a vertical portion. The horizontal portion of the nitride material 108 is adjacent to (e.g., on, directly on, directly contacting) the first oxide material 106 and a vertical portion of the nitride material 108 is adjacent to (e.g., on, directly on, directly contacting) the STI structures 104. The vertical portion of the nitride material 108 is also adjacent to the first oxide material 106, the horizontal portion of the nitride material 108, and the second oxide material 110, such as being on sidewalls of the first oxide material 106, the horizontal portion of the nitride material 108, and the second oxide material 110. Although the nitride material 108 is illustrated in FIG. 1A as being a single material, the nitride material 108 may include multiple portions of a nitride material formed at different stages of the fabrication process. The second oxide material 110 is adjacent to the horizontal portion and vertical portion of the nitride material 108. The apparatus 100 includes a first opening 112 between adjacent STI structures 104, and a second opening 114 above (e.g., over) the first opening 112 and adjacent to the nitride material 108. The first opening 112 and the second opening 114 are formed by conventional techniques. Dimensions of the first opening 112 include a critical dimension (CD) (e.g., width W in the X-direction) and a trench depth (e.g., height H₁ in the Z-direction). The second opening 114 is located above (e.g., over) the first opening 112 and between (e.g., within) sidewalls of the nitride material 108. The second opening 114 extends from a top surface of the vertical portion of the nitride material 108 to a top surface of the STI structures 104 and the top of the first opening 112.

The first opening 112 may be at least partially defined by opposing side surfaces (e.g., opposing sidewalls) of the STI structures 104 and by an upper surface of the active area 102, which is recessed relative to other active areas 102. The sidewalls of the STI structures 104 defining the first opening 112 may be vertical or substantially vertical. The upper surfaces of the STI structures 104 may define upper horizontal boundaries (e.g., in the X-direction) of the first opening 112. The shape and dimensions of the first opening 112 may at least partially depend upon the shapes and dimensions of desired features (e.g., structures) to be formed within the first opening 112. By way of non-limiting example, the first opening 112 may exhibit a columnar shape (e.g., a substantially rectangular columnar cross-sectional shape) having a width W in the X-direction less than or equal to about 35 nm, and a height H₁ in the Z-direction within the range of from about 5 nm to about 30 nm.

The second opening 114 may be at least partially defined by opposing side surfaces (e.g., opposing sidewalls) of the vertical portions of the nitride material 108, and upper surfaces of the STI structures 104 may define a lower horizontal boundary (e.g., in the X-direction) of the second opening 114. The sidewalls of the nitride material 108 defining the second opening 114 may be vertical, substantially vertical, or sloped. The shape and dimensions of the second opening 114 may at least partially depend upon the shapes and dimensions of desired features (e.g., structure) to be formed within the second opening 114.

The semiconductor structure 101 at the process stage shown in FIG. 1A may be formed by conventional techniques. The active areas 102 are formed of silicon, such as a monocrystalline silicon, a doped monocrystalline silicon, or a polysilicon and may be isolated from one another by the STI structures 104, which are formed of a nitride material (e.g., a silicon nitride (SiN), an oxynitride). By way of example only, the active areas 102 may be formed of silicon and the STI structures 104 may be formed of silicon nitride. The first oxide material 106 and the second oxide material 110 may each be formed of the same oxide material, or may be formed of different oxide materials. The first oxide material 106 and the second oxide material 110 may include, but are not limited to, a silicon oxide material. The nitride material 108 may be formed of a material that is selectively etchable relative to one or more other dielectric materials used during the fabrication process. The nitride material 108 may include, but is not limited to, a silicon nitride material, a silicon oxynitride material, a silicon carbon nitride material, or a silicon carboxynitride material. The nitride material 108 may, for example, be a silicon nitride material.

Referring next to FIG. 1B, a liner 116 may be formed within the first opening 112 and the second opening 114 of the semiconductor structure 101, such as on exposed surfaces of the nitride material 108, the STI structures 104, and the active area 102. The liner 116 may extend (e.g., continuously extend) over the exposed surfaces of the semiconductor structure 101 and may partially fill (e.g., less than completely fill) the first opening 112 and the second opening 114. The liner 116 may substantially conform to a topography defined by the sidewalls of the nitride material 108 and the STI structures 104 within the first opening 112 and the second opening 114. The liner 116 may extend over surfaces (e.g., top surfaces) of the second oxide material 110 and the nitride material 108 of the semiconductor structure 101. The liner 116 may extend laterally (e.g., in the Z-direction) over side surfaces of the nitride material 108. The liner 116 may extend over surfaces (e.g., top surfaces) and laterally (e.g., in the Z-direction) over side surfaces of the STI structures 104 adjacent to the first opening 112 and second opening 114. The liner 116 may extend over surfaces (e.g., top surfaces) of the active area 102 adjacent to the first opening 112.

The liner 116 may be formed of and include the silicon carbide (SiC) or the doped silicon carbide material, such as SiC, silicon carbon oxide (SiC_{y}Oₓ), or silicon carbon nitride (SiCN_{y}), wherein an atomic percentage (at. %) of carbon within the liner 116 is within a range of from about 0.1 at. % to about 20 at. %, such as from about 6 at. % to about 15 at. %, from 8 at. % to about 15 at. %, from about 10 at. % to about 20 at. %, from about 10 at. % to about 15 at. %, or from about 8 at. % to about 10 at. %. The liner 116 may be formed by CVD, ALD, or other technique suitable for forming the liner 116 at a desired thickness and at a high degree of conformality. In some embodiments, the liner 116 is silicon carbon oxide. One or more of the carbon atoms of the silicon carbon oxide are bonded to the silicon atoms. In other embodiments, the liner 116 is silicon carbon nitride. The liner 116 may be formed at a temperature of from about 200° C. to about 700° C., such as from about 300° C. to about 600° C., or from about 375° C. to about 550° C.

A thickness of the liner 116 may at least partially depend on the desired dimension (e.g., width in the X-direction) of the features formed in the first opening 112 during subsequent process acts. The liner 116 may be formed at a minimum thickness that provides a substantially continuous material over the exposed surfaces of the semiconductor structure 101. In other words, the liner 116 does not include gaps, pinholes, etc. The liner 116 may be formed at a thickness within a range of from about 1 nm to about 15 nm, such as from about 1 nm to about 10 nm, from about 1 nm to about 8 nm, from about 1 nm to about 7 nm, from about 3 nm to about 10 nm, or from about 3 nm to about 8 nm. By way of example only, the liner 116 may be about 1 nm thick, which reduces the width of the first opening 112 by about 2 nm and enables smaller features (e.g., smaller than the CD of the first openings 112) to be formed, as described below. Since the liner 116 is formed at a high degree of conformality, the liner 116 is substantially uniform in its thickness.

Referring next to FIG. 1C, the liner 116 may be subjected to (e.g., exposed to) one or more treatment acts (indicated by arrows) that change (e.g., reduce) the carbon content of desired portions of the liner 116, which changes the chemical composition of the portions of the liner 116 compared to the composition of the liner 116 as initially formed. The treatment act may include exposing the liner 116 to a plasma treatment act (e.g., an oxygen gas (O₂) plasma treatment act). For example, the oxygen atoms of the plasma treatment replace the carbon atoms of the liner material, therefore reducing the carbon content of the liner 116. The portions of the liner 116 exposed to the plasma may be the portions of the liner 116 adjacent to (e.g., on) the horizontal surfaces of the second oxide material 110 and the horizontal surfaces of the vertical portion of the nitride material 108, and adjacent to (e.g., on) the horizontal surfaces of the STI structures 104 and the horizontal surfaces of the active areas 102. For instance, the horizontally-oriented portions of the liner 116 may be exposed to the plasma, forming treated liner portions 118, while portions of the liner 116 on the sidewalls of the nitride material 108 and on the sidewalls of the STI structures 104 are not substantially exposed to the plasma. Following the plasma treatment act, the exposed portions (e.g., horizontal portions) of the liner 116 exhibit a decreased amount of carbon relative to the unexposed portions (e.g., portions on the sidewalls of the nitride material 108 and the sidewalls of the STI structures 104) of the liner 116. By way of example only, the horizontal portions of the liner 116, following exposure to the plasma, may be substantially free of carbon, such that the horizontal portions of the liner 116 include no (e.g., 0 at. %) carbon.

To prevent damage to the portions of the liner 116 that are not oriented horizontally (e.g., the unexposed portions), the plasma treatment act may be a highly directional plasma treatment act where the direction of the flow of ions is controlled (e.g., biased). A light bias may be used to selectively expose the horizontal portions of the liner 116 to the plasma. The bias may range from about 300 V to about 700 V, such as about 400 V or about 600 V. Therefore, only the horizontally-oriented portions of the liner 116 are reduced in carbon content following the plasma treatment act. The unexposed portions of the liner 116 remain substantially unaffected following the plasma treatment act and exhibit a material composition that is substantially the same as the material composition of the liner 116 as initially formed. The portions (e.g., the treated liner portions 118) of the liner 116 affected (e.g., damaged) by the plasma treatment exhibit a material composition that is different from the material composition of the liner 116 as initially formed.

The plasma may be a reducing plasma that includes, but is not limited to, an O₂ plasma, an O₂/hydrogen gas (H₂)/nitrogen gas (N₂) plasma, an H₂/N₂ plasma, or an O₂/fluorocarbon plasma. The plasma may also include an inert gas, such as argon. In some embodiments, the plasma includes 100 weight percent (wt %) O₂. Process conditions for the plasma treatment act, such as time, RF power, exhaust power, gas mixture, flow rate, etc., may be chosen depending on the composition of the plasma utilized for the treatment act and the desired directionality of the plasma treatment act. In addition, the shape and dimensions of the first opening 112 and second opening 114 may affect the process conditions utilized during the plasma treatment act. An opening with a smaller CD (e.g., width in the X-direction) than another opening with a larger CD may utilize increased RF power, increased exhaust power, and an increased flow rate to achieve the same amount of damage to the horizontal portions of the liner 116. The thickness of the liner 116 may affect the process conditions utilized during the plasma treatment act. A liner 116 with a greater thickness may utilize increased RF power, increased exhaust power, and an increased flow rate to achieve the same amount of damage to the horizontal portions of the liner 116.

The horizontal portions of the liner 116 exposed to the plasma are referred to as the treated liner portions 118, and are shown in FIG. 1C and subsequent drawings as treated liner portions 118, indicating that the plasma treatment act has been conducted. The treated liner portions 118 exhibit a reduced carbon content compared to the remaining (e.g., untreated) portions of the liner 116 as a result of the plasma treatment. After conducting the plasma treatment, the treated liner portions 118 may contain substantially no carbon. Exposing the liner 116 to the plasma decreases the carbon content in the horizontally-oriented portions of the liner 116 and increases the oxygen content. If, for example, the liner 116 is formed from silicon carbon oxide, the portions of the silicon carbon oxide exposed to the plasma are converted to a silicon oxide (SiOₓ) material by the plasma treatment. The SiOₓ material of the treated liner portions 118 is selectively removable (e.g., selectively etchable) relative to the silicon carbon oxide of the untreated portions of the liner 116. The different chemical compositions of the treated liner portions 118 and the remaining portions of the liner 116 provide etch selectivity during subsequent process acts.

Referring next to FIG. 1D, the treated liner portions 118 may be selectively removed from the horizontal surfaces of the nitride material 108, the upper surfaces of the second oxide material 110, the upper surfaces of the STI structures 104, and the upper surfaces of the active area 102. For instance, the treated liner portions 118 may be removed, while the portions of the liner 116 remain on the sidewalls of the nitride material 108 and the sidewalls of the STI structures 104. The treated liner portions 118 may be removed (e.g., etched) by a selective etch (e.g., an isotropic etch) process, such as a wet etch process, or a vapor etch process. By way of non-limiting example, the treated liner portions 118 may be removed by a wet etch process. By using a highly selective, wet etch process, the treated liner portions 118 may be easily removed from the first opening 112. The portions of the liner 116 remaining in the first opening 112 may exhibit substantially vertical sidewalls and substantially square corners following the wet etch process. In other words, an angle α defined by an intersection between an upper surface of the STI structures 104 and a sidewall (e.g., vertically oriented portion) of the liner 116 remaining in the first opening 112 may range between about 85 degrees and about 100 degrees, such as between about 87 degrees and about 95 degrees, between about 88 degrees and about 93 degrees. In some embodiments, the angle α is about 90 degrees. The highly selective, wet etch process may also enable tailoring of the thickness of the liner 116 remaining on the sidewalls of the STI structures 104 because substantially no liner 116 is removed from the sidewalls by the process. The liner 116 remaining in the first opening 112 may reduce the width of the first opening 112 from its initial width W to a width W′, which is equal to the initial width W minus two times the thickness of the liner 116. For example, the reduced width W′ may be less than or equal to 33 nm.

The portions of the liner 116 remaining in the second opening 114 may exhibit sloped sidewalls or substantially vertical sidewalls following the wet etch process. The liner 116 remaining in the second opening 114 may, therefore, exhibit substantially square corners or corners that exhibit an angle greater than 90 degrees (i.e., an obtuse angle). For instance, an angle β defined by the intersection between an upper surface of the nitride material 108 and a sidewall of the liner 116 remaining in the second opening 114 may be greater than or equal to about 95 degrees, such as from about 95 degrees to about 105 degrees. The conditions of the wet etch process used to remove the treated liner portions 118 do not remove portions of the STI structures 104, which are also exposed to the wet etch chemistry. In other words, the treated liner portions 118 are also selectively removed relative to the STI structures 104. Therefore, the exposed surfaces of the STI structures 104 are substantially unaffected by the wet etch process and no shoulders are formed.

By way of non-limiting example, if the liner 116 is formed from a silicon carbon oxide material, the treated liner portions 118 may be selectively removed using an aqueous hydrogen fluoride (HF) solution. The etch chemistry and etch conditions may be selected to substantially remove the treated liner portions 118, while the liner 116 remains on the sidewalls of the STI structures 104 in the first opening 112 and on the sidewalls of the nitride material 108 in the second opening 114. The STI structures 104 and the active areas 102 may be substantially unaffected by the etch chemistry and etch conditions used. While the liner 116 in FIG. 1B is shown as being a substantially continuous material, the liner 116 in FIG. 1D becomes discontinuous following the wet etch process.

The remaining portions of the liner 116 in the first opening 112 may exhibit a substantially similar height H₁ as the height H₁ of the first opening 112, such as between about 95% and about 105% of the height H₁ of the first opening 112. The liner 116 may also exhibit the substantially square corners. In contrast, if conventional dry etch processes are used to remove a portion of a silicon nitride liner during a similar stage of fabrication of a conventional apparatus, the remaining liner would include rounded corners. Additionally, if the silicon nitride liner portions of a conventional apparatus were removed by the conventional dry etch process, the exposed areas of the STI structures would exhibit increased damage due to ion bombardment from the plasma. Following the conventional dry etch process, the STI structures of the conventional apparatus would exhibit a sloped profile (e.g., shoulders) in contrast to the substantially horizontal surfaces and substantially vertical sidewalls of the STI structures 104 achieved by the methods according to embodiments of the disclosure.

Referring next to FIG. 1E, a conductive material 122 may be formed in the first opening 112, adjacent to (e.g., over) the recessed active areas 102 of the semiconductor structure 101 of the apparatus 100. The conductive material 122 may at least partially fill the first opening 112. Excess conductive material 122 may be removed by conventional techniques to recess the conductive material 122 in the first opening 112. The conductive material 122 may extend vertically (e.g., in the Z-direction) from the horizontal (e.g., top surface) surface of the recessed active areas 102 to a predetermined height (e.g., dimension in the Z-direction) within the first opening 112. The conductive material 122 may extend horizontally (e.g., in the X-direction) between the sidewalls of the remaining portions of the liner 116 in the first opening 112. The conductive material 122 may, for example, be polysilicon or a metal material. The width of the conductive material 122 (e.g., dimension in the X-direction) may be substantially equal to the reduced width W′ of the first opening 112. Therefore, the conductive material 122 exhibits a smaller width W′ than the width W of the first opening 112.

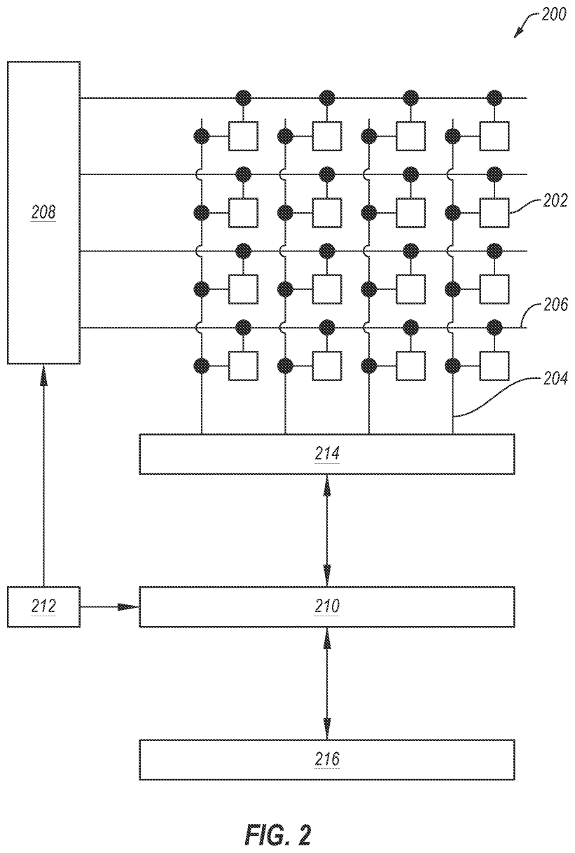

Referring next to FIG. 1F, a contact 124 (e.g., a digit line contact, a bit line contact) may be formed adjacent to (e.g., over) the conductive material 122. The contact 124 may extend vertically (e.g., in the Z-direction) from the horizontal (e.g., top surface) surface of the conductive material 122 to a predetermined height (e.g., dimension in the Z-direction) within the second opening 114. The contact 124 may be formed of at least one conductive material. In subsequent process acts, the second oxide material 110 and a portion of the nitride material 108 may be removed, and a digit line 126 (e.g., bit line) may be formed adjacent to (e.g., over) the nitride material 108, the liner 116, and the contact 124. The contact 124 extends vertically to the digit line 126 (e.g., extends longitudinally relative to the height of the apparatus 100), to enable electrical communication with more distal components of a microelectronic device 200 (see FIG. 2) that includes the apparatus 100. The digit line 126 may be formed of at least one conductive material. The conductive material of the digit line 126 may be the same as or different than the conductive material of the contact 124. The widths of the conductive material 122 and the contact 124 may be less than the width of the first opening 112, less than the width of the STI structures 104, and less than the width of the active areas 102, which improves contact resistance properties of the microelectronic device 200 that includes the apparatus 100.

Forming the liner 116, conducting the plasma treatment act, and conducting the wet etch act according to embodiments of the disclosure enables corner regions of the liner 116 (FIGS. 1D, 1E, 1F) remaining in the first opening 112 to be substantially square in cross-section. In addition, the treated liner portions 118 may be removed without damaging exposed materials of the semiconductor structure 101, such as the STI structures 104. Therefore, in addition to improved contact resistance properties, a microelectronic device 200 that includes the apparatus 100 may also exhibit reduced shorting. The combination of the plasma treatment act and the wet etch act produce desired profiles of the liner 116 compared to conventional dry etch processes. The remaining portions of the liner 116 may function to decrease the width of the first opening 112 before forming the conductive material 122 and contact 124 in the first opening 112. Therefore, methods according to embodiments of the disclosure may be used to form the conductive material 122 and the contact 124 having a smaller width W′ than the width W of the first opening 112 without conducting a dry etch process. By reducing the width of the first opening 112 to the smaller width W′, the resulting apparatus 100 including the conductive material 122 and the contact 124 may exhibit improved electrical performance compared to an apparatus formed using a conventional dry etch process.

Accordingly, a method of forming an apparatus is disclosed. The method comprises exposing a silicon carbide material on sidewalls of shallow trench isolation structures to a plasma. Horizontal portions of the silicon carbide material are exposed to a greater concentration of ions of the plasma than vertical portions of the silicon carbide material. The horizontal portions of the silicon carbide material are removed without substantially removing the vertical portions of the silicon carbide material on the sidewalls of the shallow trench isolation structures. The one or more conductive materials are formed between opposing sidewalls of the silicon carbide material.

Accordingly, another method of forming an apparatus is disclosed. The method comprises forming a silicon carbide material on sidewalls of shallow trench isolation structures. The silicon carbide material is subjected to a plasma to expose horizontal portions of the silicon carbide material to the plasma. The horizontal portions of the silicon carbide material are selectively removed. A conductive material is formed between vertical portions of the silicon carbide material on sidewalls of the shallow trench isolation structures and adjacent to an active area.

An apparatus (e.g., the apparatus 100 previously described with reference to FIGS. 1A-1F) may be subjected to additional processing acts to form a microelectronic device 200 containing the apparatus, as shown in FIG. 2. Such additional processing acts may employ conventional processes and conventional processing equipment. The microelectronic device 200 may include, for example, one or more of the apparatus 100 previously described herein. FIG. 2 shows a functional block diagram of the microelectronic device 200 (e.g., a DRAM device, a memory device), in accordance with embodiments of the disclosure. As shown in FIG. 2, the microelectronic device 200 includes memory cells 202 that may include one or more of the apparatus 100, digit lines 204 (e.g., the digit lines 126 of apparatus 100 previously described with reference to FIG. 1F), word lines 206, a row decoder 208, a column decoder 210, a memory controller 212, a sense device 214, and an input/output device 216.

The memory cells 202 of the microelectronic device 200 are programmable to at least two different logic states (e.g., logic 0 and logic 1). Each memory cell 202 may individually include a capacitor and a transistor. The capacitor stores a charge representative of the programmable logic state (e.g., a charged capacitor may represent a first logic state, such as a logic 1; and an uncharged capacitor may represent a second logic state, such as a logic 0) of the memory cell 202. The transistor grants access to the capacitor upon application (e.g., by way of one of the word lines 206) of a minimum threshold voltage to a semiconductive channel thereof for operations (e.g., reading, writing, rewriting) on the capacitor. The transistor may be operably coupled to the capacitor by way of a conductive contact structure in electrical communication with and extending between the transistor and the capacitor.

The digit lines 204 (e.g., the digit lines 126) are connected to the capacitors of the memory cells 202 by way of the transistors of the memory cells 202. The digit lines 204 may be separated (e.g., electrically isolated) from the conductive contact structures extending between the transistors and the capacitors of the memory cells 202. The word lines 206 extend perpendicular to the digit lines 204, and are connected to gates of the transistors of the memory cells 202. Operations may be performed on the memory cells 202 by activating appropriate digit lines 204 and word lines 206. Activating a digit line 204 or a word line 206 may include applying a voltage potential to the digit line 204 or the word line 206. Each column of memory cells 202 may individually be connected to one of the digit lines 204, and each row of the memory cells 202 may individually be connected to one of the word lines 206. Individual memory cells 202 may be addressed and accessed through the intersections (e.g., cross points) of the digit lines 204 and the word lines 206.

The memory controller 212 may control the operations of the memory cells 202 through various components, including the row decoder 208, the column decoder 210, and the sense device 214. The memory controller 212 may generate row address signals that are directed to the row decoder 208 to activate (e.g., apply a voltage potential to) predetermined word lines 206, and may generate column address signals that are directed to the column decoder 210 to activate (e.g., apply a voltage potential to) predetermined digit lines 204. The memory controller 212 may also generate and control various voltage potentials employed during the operation of the microelectronic device 200. In general, the amplitude, shape, and/or duration of an applied voltage may be adjusted (e.g., varied), and may be different for various operations of the microelectronic device 200.

During use and operation of the microelectronic device 200, after being accessed, a memory cell 202 may be read (e.g., sensed) by the sense device 214. The sense device 214 may compare a signal (e.g., a voltage) of an appropriate digit line 204 to a reference signal in order to determine the logic state of the memory cell 202. If, for example, the digit line 204 has a higher voltage than the reference voltage, the sense device 214 may determine that the stored logic state of the memory cell 202 is a logic 1, and vice versa. The sense device 214 may include transistors and amplifiers to detect and amplify a difference in the signals. The detected logic state of a memory cell 202 may be output through the column decoder 210 to the input/output device 216. In addition, a memory cell 202 may be set (e.g., written) by similarly activating an appropriate word line 206 and an appropriate digit line 204 of the microelectronic device 200. By controlling the digit line 204 while the word line 206 is activated, the memory cell 202 may be set (e.g., a logic value may be stored in the memory cell 202). The column decoder 210 may accept data from the input/output device 216 to be written to the memory cells 202. Furthermore, a memory cell 202 may also be refreshed (e.g., recharged) by reading the memory cell 202. The read operation will place the contents of the memory cell 202 on the appropriate digit line 204, which is then pulled up to full level (e.g., full charge or discharge) by the sense device 214. When the word line 206 associated with the memory cell 202 is deactivated, all of memory cells 202 in the row associated with the word line 206 are restored to full charge or discharge.

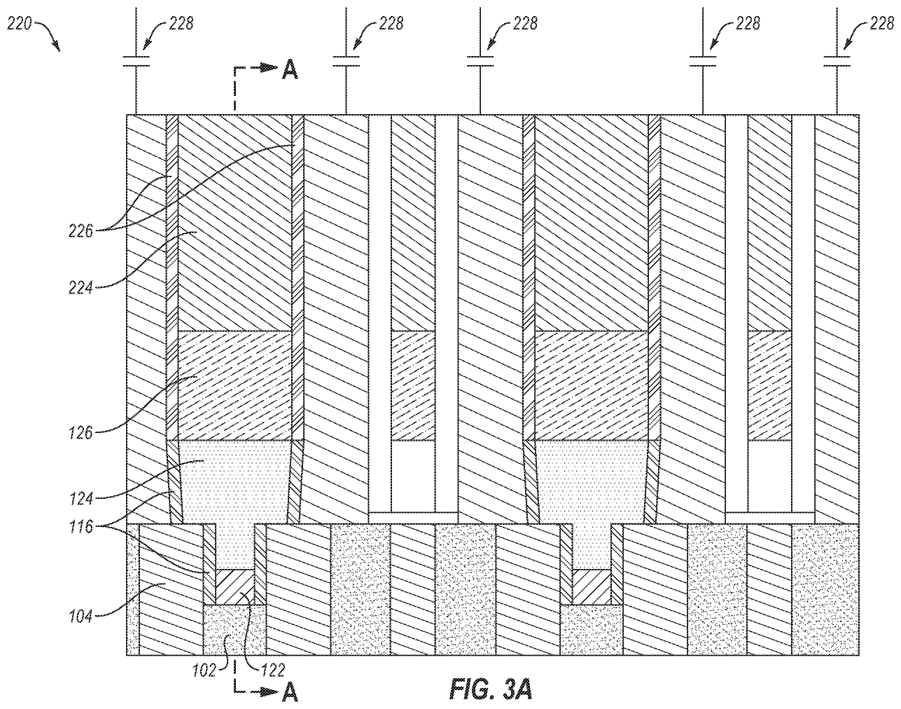

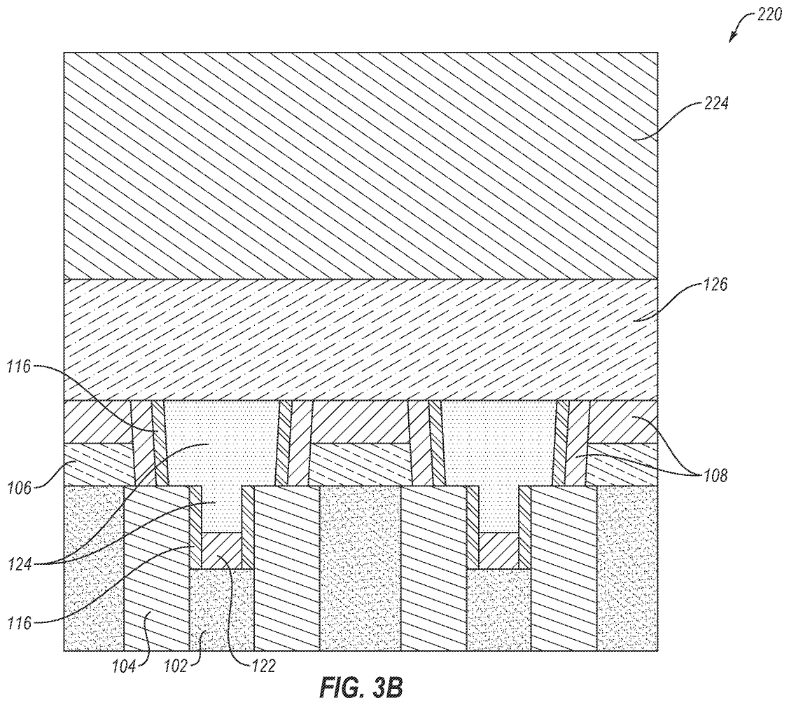

An apparatus (e.g., the apparatus 100 previously described with reference to FIGS. 1A-1F) may be subjected to additional processing acts to form a microelectronic device 220 containing the apparatus (e.g., the apparatus 100 previously described with reference to FIGS. 1A-1F), as shown in FIGS. 3A-3B. Such additional processing acts may employ conventional processes and conventional processing equipment. The microelectronic device 220 may include, for example, one or more of the apparatus 100 previously described. FIGS. 3A-3B shows a cross-sectional view of a portion of microelectronic device 220 (e.g., a DRAM device, a memory device), in accordance with embodiments of the disclosure. As shown in FIGS. 3A-3B, the microelectronic device 220 includes liner 116, active areas 102, STI structures 104, first oxide material 106, nitride material 108, conductive material 122, contact 124 (e.g., digit line contact), digit line 126, insulative cap material 224, spacers 226, and capacitors 228. The conductive material 122 may be located adjacent (e.g., vertically adjacent) to active areas 102 and adjacent (e.g., laterally adjacent) to liner 116. The STI structures 104 may be located adjacent (e.g., laterally adjacent) to the active areas 102 and the liner 116. The liner 116 may be located adjacent (e.g., laterally adjacent) to a portion of the contact 125 and over the active areas 102. The contact 124 may be located adjacent (e.g., vertically adjacent) to and over the conductive material 122. The digit line 126 may be located adjacent (e.g., vertically adjacent) to and over contact 124. The insulative cap material 224 may be located adjacent (e.g., vertically adjacent) to and over the digit line 126. The spacers 226 may be laterally adjacent to the conductive material 122, the contact 124, the digit line 126, and the insulative cap material 224. The contact 124 may be laterally adjacent to the liner 116. The capacitors 228 may be electrically connected to the digit line 126, the contact 124, and the conductive material 122. FIG. 3B shows cross-sectional view A-A of microelectronic device 220. With reference to FIG. 3B, the first oxide material 106 may be located adjacent (e.g., vertically adjacent) to and over STI structures 104 and active areas 102, and may be located adjacent (e.g., laterally adjacent) to the nitride material 108. The nitride material 108 may be located adjacent (e.g., vertically adjacent) to and over the first oxide material 106 and may be located adjacent (e.g., laterally adjacent) to the liner 116. The digit line 126 may be located adjacent (e.g., vertically adjacent) to and over the nitride material 108, the liner 116, and the contact 124. The insulative cap material 224 may be located adjacent (e.g., vertically adjacent) to and over the digit line 126.

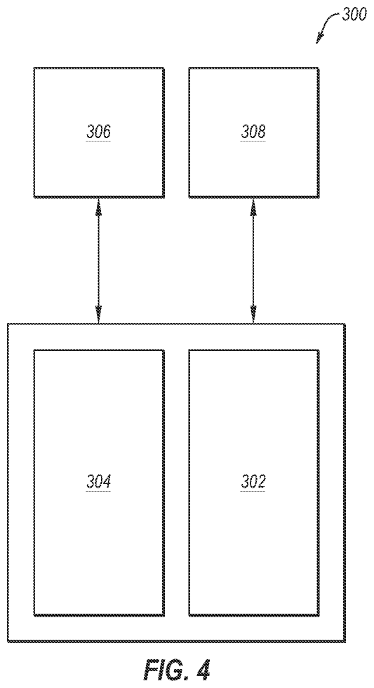

Apparatuses (e.g., the apparatus 100) and microelectronic devices (e.g., the microelectronic device 200, 220 previously described with reference to FIGS. 2, 3A-3B) may be used in embodiments of electronic systems according to embodiments of the disclosure. Additional processing acts may be performed to form the electronic systems that contain one or more apparatus 100 or one or more microelectronic devices 200, 220. For example, FIG. 4 is a block diagram of an illustrative electronic system 300 according to embodiments of the disclosure. The electronic system 300 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, a navigation device, etc. The electronic system 300 includes at least one memory device 302. The memory device 302 may comprise, for example, an embodiment of one or more of an apparatus (e.g., the apparatus 100) and a microelectronic device (e.g., the microelectronic device 200, 220). The electronic system 300 may further include at least one electronic signal processor device 304 (often referred to as a “microprocessor”). The electronic signal processor device 304 may, optionally, include an embodiment of an apparatus (e.g., the apparatus 100 previously described with reference to FIGS. 1A-1F) and a microelectronic device (e.g., the microelectronic device 200, 220 previously described with reference to FIGS. 2, 3A-3B) previously described herein. The electronic system 300 may further include one or more input devices 306 for inputting information into the electronic system 300 by a user, such as, for example, a mouse or other pointing device, a keyboard, a touchpad, a button, or a control panel. The electronic system 300 may further include one or more output devices 308 for outputting information (e.g., visual or audio output) to a user such as, for example, a monitor, a display, a printer, an audio output jack, a speaker, etc. In some embodiments, the input device 306 and the output device 308 may comprise a single touchscreen device that can be used both to input information to the electronic system 300 and to output visual information to a user. The input device 306 and the output device 308 may communicate electrically with one or more of the memory device 302 and the electronic signal processor device 304.

The apparatuses (e.g., the apparatus 100 (FIGS. 1A-1F)), microelectronic devices (e.g., the microelectronic device 200, 220 (FIGS. 2, 3A-3B)), electronic systems (e.g., the electronic system 300 (FIG. 4)), and methods of the disclosure facilitate improved electrical performance, reduced costs (e.g., manufacturing costs, material costs), and increased miniaturization of components as compared to conventional structures, conventional apparatuses, conventional devices, conventional systems, and conventional methods. The structures, apparatuses, microelectronic devices, electronic systems, and methods of the disclosure may also improve scalability, efficiency, and simplicity as compared to conventional structures, conventional apparatuses, conventional devices, conventional systems, and conventional methods.

Accordingly, an apparatus is disclosed. The apparatus comprises active areas and shallow trench isolation structures on a base material. A first conductive material is vertically adjacent to an active area of the active areas and is between laterally adjacent shallow trench isolation structures. A second conductive material is vertically adjacent to the first conductive material and is between the laterally adjacent shallow trench isolation structures. A silicon carbide material is on sidewalls of the shallow trench isolation structures, the silicon carbide material exhibiting substantially vertical sidewalls. An oxide material is adjacent to the active areas and shallow trench isolation structures. A nitride material is adjacent to the oxide material, and a digit line is adjacent to the second conductive material.

Accordingly, an electronic system is disclosed and comprises one or more microelectronic devices. The one or more electronic devices comprise digit lines, word lines operably coupled to the digit lines, and memory cells operably coupled to the digit lines and the word lines. One or more memory cells comprise a digit line contact operably coupled to a respective digit line. A silicon carbide material is on sidewalls of the digit line contact, the silicon carbide material comprising a carbon content of from about 0.1 atomic percent to about 20 atomic percent. A conductive material is vertically adjacent to the digit line contact, shallow trench isolation structures are laterally adjacent to the silicon carbide material, and active areas are laterally adjacent to the shallow trench isolation structures.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternate useful combinations of the elements described, will become apparent to those skilled in the art from the description. Such modifications and embodiments also fall within the scope of the appended claims and equivalents.

What is claimed is:

1. An apparatus comprising:
active areas and shallow trench isolation structures on a base material;
a first conductive material vertically adjacent to an active area of the active areas and between laterally adjacent shallow trench isolation structures;
a second conductive material vertically adjacent to the first conductive material and between the laterally adjacent shallow trench isolation structures;
a silicon carbide material on sidewalls of the shallow trench isolation structures, the silicon carbide material exhibiting substantially vertical sidewalls;
an oxide material adjacent to the active areas and shallow trench isolation structures;
a nitride material adjacent to the oxide material; and
a digit line adjacent to the second conductive material.

2. The apparatus of claim 1, wherein the silicon carbide material comprises a carbon content of from about 0.1 atomic percent to about 20 atomic percent.

3. The apparatus of claim 1, wherein the silicon carbide material comprises a doped silicon carbide material selected from the group consisting of a silicon carbon oxide material, a silicon carbon nitride material, a silicon carboxynitride material, and a silicon boronitrocarbide material.

4. The apparatus of claim 1, wherein an interface between the first conductive material and the active area vertically adjacent to the first conductive material is substantially free of damage.

5. The apparatus of claim 1, wherein corners of the silicon carbide material are substantially square in cross-section.

6. The apparatus of claim 1, wherein a width of the active areas is less than or equal to about 35 nm.

7. The apparatus of claim 1, wherein a width of the first conductive material is less than a width of the active areas.

8. The apparatus of claim 1, further comprising the silicon carbide material on sidewalls of the nitride material.

9. An electronic system comprising:
one or more microelectronic devices comprising digit lines, word lines operably coupled to the digit lines, and memory cells operably coupled to the digit lines and the word lines, one or more of the memory cells comprising:
a digit line contact operably coupled to a respective digit line;
a silicon carbide material on sidewalls of the digit line contact, the silicon carbide material comprising a carbon content of from about 0.1 atomic percent to about 20 atomic percent;
a conductive material vertically adjacent to the digit line contact;
shallow trench isolation structures laterally adjacent to the silicon carbide material; and
active areas laterally adjacent to the shallow trench isolation structures.

10. A method of forming an apparatus, comprising:
exposing a silicon carbide material on sidewalls of shallow trench isolation structures to a plasma, horizontal portions of the silicon carbide material exposed to a greater concentration of ions of the plasma than vertical portions of the silicon carbide material;
removing the horizontal portions of the silicon carbide material without substantially removing the vertical portions of the silicon carbide material on the sidewalls of the shallow trench isolation structures; and
forming one or more conductive materials between opposing sidewalls of the silicon carbide material.

11. The method of claim 10, wherein exposing a silicon carbide material to a plasma comprises converting the horizontal portions of the silicon carbide material to a silicon oxide material.

12. The method of claim 10, wherein removing the horizontal portions of the silicon carbide material without substantially removing the vertical portions of the silicon carbide material comprises forming the vertical portions of the silicon carbide material with substantially vertical sidewalls and square corners.

13. The method of claim 10, wherein exposing a silicon carbide material on sidewalls of shallow trench isolation structures to a plasma comprises exposing the silicon carbide material on the sidewalls of the shallow trench isolation structures to an oxygen plasma.

14. The method of claim 10, wherein removing the horizontal portions of the silicon carbide material comprises exposing the silicon carbide material to a wet etchant comprising an aqueous hydrofluoric acid (HF) solution.

15. A method of forming an apparatus, comprising:
forming a silicon carbide material on sidewalls of shallow trench isolation structures;
subjecting the silicon carbide material to a plasma to expose horizontal portions of the silicon carbide material to the plasma;
selectively removing the horizontal portions of the silicon carbide material; and
forming a conductive material between vertical portions of the silicon carbide material on sidewalls of the shallow trench isolation structures and adjacent to an active area.

16. The method of claim 15, wherein forming a silicon carbide material on sidewalls of shallow trench isolation structures comprises conformally forming the silicon carbide material on the shallow trench isolation structures.

17. The method of claim 15, wherein subjecting the silicon carbide material to a plasma to expose horizontal portions of the silicon carbide material to the plasma comprises reducing a carbon content of the horizontal portions of the silicon carbide material.

18. The method of claim 17, wherein reducing a carbon content of the horizontal portions of the silicon carbide material comprises converting the horizontal portions of the silicon carbide material to be substantially free of carbon.

19. The method of claim 15, further comprising forming a digit line contact over the conductive material and adjacent to the vertical portions of the silicon carbide material.

20. The method of claim 19, further comprising forming a digit line over the digit line contact and adjacent to the vertical portions of the silicon carbide material.
